(19) United States
(12) Patent Application Publication
(10) Pub. No.: US 2026/0134158 A1
(43) Pub. Date: May 14, 2026

(54) ITERATIVE ATTENTION SCOPING ON SPATIALLY CONTINGUOUS POINT CLOUD BUCKETS

(71) Applicant: GM Cruise Holdings, LLC, San Francisco, CA (US)

(72) Inventor: Liyan Chen, Austin, TX (US)

(73) Assignee: GM Cruise Holdings, LLC, San Francisco, CA (US)

(21) Appl. No.: 19/328,171

(22) Filed: Sep. 14, 2025

Related U.S. Application Data
(60) Provisional application No. 63/720,108, filed on Nov. 13, 2024.

(51) Int. Cl. G06F 30/12

(52) U.S. Cl. CPC G06F 30/12

(57) ABSTRACT

A method includes receiving a three-dimensional (3D) point cloud and generating a plurality of buckets by applying a spatial hash function to coordinates of points in the 3D point cloud. The method includes arranging, based on the spatial hash function, the points into a contiguous block of memory. The method includes performing a plurality of attention iterations. Each attention iteration includes selecting a subset of the plurality of buckets to define an attention scope for the attention iteration, loading point features corresponding to the points in the attention scope from a contiguous block of memory into a cache, generating updated point features by performing a multi-head self-attention operation on the loaded point features. The method includes generating, based on the updated point features from the plurality of attention iterations, a feature representation of the 3D point cloud.

### CROSS-REFERENCE TO RELATED APPLICATION

This application claims priority under 35 U.S.C. § 119(e) to U.S. Provisional Application Ser. No. 63/720,108, filed Nov. 13, 2024. The disclosure of this prior application is considered part of the disclosure of this application and is hereby incorporated by reference in its entirety.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to processing three-dimensional (3D) point cloud data using deep learning models, and more specifically to feature extraction from such data. Systems for analyzing 3D point clouds often utilize specialized neural network architectures, such as point transformers, to learn meaningful representations from raw spatial data for applications including autonomous driving and robotics. These transformer-based models typically employ multi-head self-attention mechanisms to capture complex geometric structures and relationships among points. To manage the computational requirements of processing large-scale point clouds, attention operations may be applied to localized groups of points. Information across different groups may be aggregated through techniques that involve processing different groupings of points in subsequent stages of a network, with computations often being executed on parallel processing hardware like graphics processing units (GPUs).

### SUMMARY

One aspect of the disclosure provides a computer-implemented method executed on data processing hardware that causes the data processing hardware to perform operations. The operations include receiving a three-dimensional (3D) point cloud and generating a plurality of buckets by applying a spatial hash function to coordinates of points in the 3D point cloud. Each respective bucket includes a corresponding group of spatially proximate points. The operations include arranging, based on the spatial hash function, the points into a contiguous block of memory. Points assigned to a same bucket are located in adjacent memory locations within the contiguous block of memory. The operations include performing a plurality of attention iterations. Each attention iteration includes selecting a subset of the plurality of buckets to define an attention scope for the attention iteration, loading point features corresponding to the points in the attention scope from the contiguous block of memory into a cache, generating updated point features by performing a multi-head self-attention operation on the loaded point features. The selection is performed without physically reordering the points within the contiguous block of memory. The operations include generating, based on the updated point features from the plurality of attention iterations, a feature representation of the 3D point cloud.

Implementations of the disclosure may include one or more of the following optional features. In some implementations, the spatial hash function includes at least one of an XOR-mod hash, an XOR-div hash, a Z-order-mod hash, or a Z-order-div hash. In these implementations, performing the plurality of attention iterations includes performing a first group of iterations using a first spatial hash function and performing a second group of iterations using a second spatial hash function different than the first spatial hash function. Selecting the subset of the plurality of buckets in a subsequent attention iteration may include selecting a shifted subset of buckets relative to a preceding attention iteration.

In some examples, the data processing hardware includes a graphics processing unit (GPU) and the cache includes a high-speed local cache of the GPU. In these examples, a size of each bucket in the plurality of buckets may align with a memory tile size of the GPU to optimize loading operations. In some implementations, the operations further include, after at least one attention iteration, performing an in-bucket pooling operation on at least one bucket of the plurality of buckets to downsample the points within the at least one bucket. In these implementations, performing the in-bucket pooling operation may include partitioning the points within the at least one bucket into a plurality of sub-buckets and applying a reduction function to the point features within each sub-bucket to generate a reduced feature vector representing each respective sub-bucket. Here, partitioning the points into the plurality of sub-buckets and applying the reduction function may be performed entirely within the cache. The operations may further include controlling a vehicle based on the feature representation of the 3D point cloud.

Another aspect of the disclosure provides a vehicle that includes data processing hardware and memory hardware in communication with the data processing hardware. The memory hardware stores instructions that when executed on the data processing hardware cause the data processing hardware to perform operations. The operations include receiving a three-dimensional (3D) point cloud and generating a plurality of buckets by applying a spatial hash function to coordinates of points in the 3D point cloud. Each respective bucket includes a corresponding group of spatially proximate points. The operations include arranging, based on the spatial hash function, the points into a contiguous block of memory. Points assigned to a same bucket are located in adjacent memory locations within the contiguous block of memory. The operations include performing a plurality of attention iterations. Each attention iteration includes selecting a subset of the plurality of buckets to define an attention scope for the attention iteration, loading point features corresponding to the points in the attention scope from the contiguous block of memory into a cache, generating updated point features by performing a multi-head self-attention operation on the loaded point features. The selection is performed without physically reordering the points within the contiguous block of memory. The operations include generating, based on the updated point features from the plurality of attention iterations, a feature representation of the 3D point cloud.

Implementations of the disclosure may include one or more of the following optional features. In some implementations, the spatial hash function includes at least one of an XOR-mod hash, an XOR-div hash, a Z-order-mod hash, or a Z-order-div hash. In these implementations, performing the plurality of attention iterations includes performing a first group of iterations using a first spatial hash function and performing a second group of iterations using a second spatial hash function different than the first spatial hash function. Selecting the subset of the plurality of buckets in a subsequent attention iteration may include selecting a shifted subset of buckets relative to a preceding attention iteration.

In some examples, the data processing hardware includes a graphics processing unit (GPU) and the cache includes a high-speed local cache of the GPU. In these examples, a size of each bucket in the plurality of buckets may align with a memory tile size of the GPU to optimize loading operations. In some implementations, the operations further include, after at least one attention iteration, performing an in-bucket pooling operation on at least one bucket of the plurality of buckets to downsample the points within the at least one bucket. In these implementations, performing the in-bucket pooling operation may include partitioning the points within the at least one bucket into a plurality of sub-buckets and applying a reduction function to the point features within each sub-bucket to generate a reduced feature vector representing each respective sub-bucket. Here, partitioning the points into the plurality of sub-buckets and applying the reduction function may be performed entirely within the cache. The operations may further include controlling a vehicle based on the feature representation of the 3D point cloud.

Another aspect of the disclosure provides a computer-readable medium having instructions that, when executed by data processing hardware, causes the data processing hardware to perform operations. The operations include receiving a three-dimensional (3D) point cloud and generating a plurality of buckets by applying a spatial hash function to coordinates of points in the 3D point cloud. Each respective bucket includes a corresponding group of spatially proximate points. The operations include arranging, based on the spatial hash function, the points into a contiguous block of memory. Points assigned to a same bucket are located in adjacent memory locations within the contiguous block of memory. The operations include performing a plurality of attention iterations. Each attention iteration includes selecting a subset of the plurality of buckets to define an attention scope for the attention iteration, loading point features corresponding to the points in the attention scope from the contiguous block of memory into a cache, generating updated point features by performing a multi-head self-attention operation on the loaded point features. The selection is performed without physically reordering the points within the contiguous block of memory. The operations include generating, based on the updated point features from the plurality of attention iterations, a feature representation of the 3D point cloud.

The details of one or more implementations of the disclosure are set forth in the accompanying drawings and the description below. Other aspects, features, and advantages will be apparent from the description and drawings, and from the claims.

### BRIEF DESCRIPTION OF THE DRAWINGS

The drawings described herein are for illustrative purposes only of selected configurations and are not intended to limit the scope of the present disclosure.

FIG. 1 is a schematic view of an example system for processing a three-dimensional point cloud.

FIG. 2 is a schematic view of an example process for performing attention iterations on point cloud data.

FIG. 3 is a flowchart of an exemplary arrangement of operations for a computer-implemented method for performing iterative attention scoping on spatially contagious point cloud buckets.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure. 7

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The analysis of three-dimensional (3D) point cloud data is an important task in various fields, including autonomous navigation, robotics, and augmented reality. These applications rely on accurately and efficiently extracting meaningful features and semantic information from large sets of unstructured 3D points captured by sensors such as light detection and ranging (LiDAR). Deep learning models, particularly those based on the transformer architecture, have become a prominent tool for this purpose, demonstrating a strong capacity to model complex spatial relationships within point cloud data.

At the core of these transformer models is the self-attention mechanism, which allows the model to weigh the importance of different points when constructing a feature representation. For large point clouds, which may include hundreds of thousands or even millions of points, computing global self-attention (e.g., where every point attends to every other point) is computationally prohibitive. Consequently, a common approach is to employ windowed or localized attention, where attention computations are restricted to smaller, spatially proximate groups of points. This strategy effectively captures local geometric details. To enable the model to learn global context and facilitate the flow of information across these distinct local windows, it is necessary to vary the point groupings between successive processing stages. One method for achieving this involves physically reordering or shuffling the points in memory according to a new partitioning scheme after each stage of local attention. For instance, after features are computed for an initial set of local windows, the entire point cloud is rearranged in memory to form a new set of windows for the next stage, allowing points that were previously in separate windows to interact.

This process of repeatedly reordering a large number of points in a global memory system may introduce a significant performance bottleneck. Modern parallel processing hardware, such as graphics processing units (GPUs), achieves maximum throughput by operating on large, contiguous blocks of data. The global shuffling operation, however, often results in scattered and non-contiguous memory access patterns, where data must be read from and written to many disparate memory locations. This type of random memory access severely underutilizes the available memory bandwidth, causing the data movement to become substantially slower than the on-chip computations. As this inefficient shuffling operation is repeated multiple times throughout the network, it may dominate the overall processing time, increasing latency and limiting the scalability of the model to larger point clouds and more complex architectures.

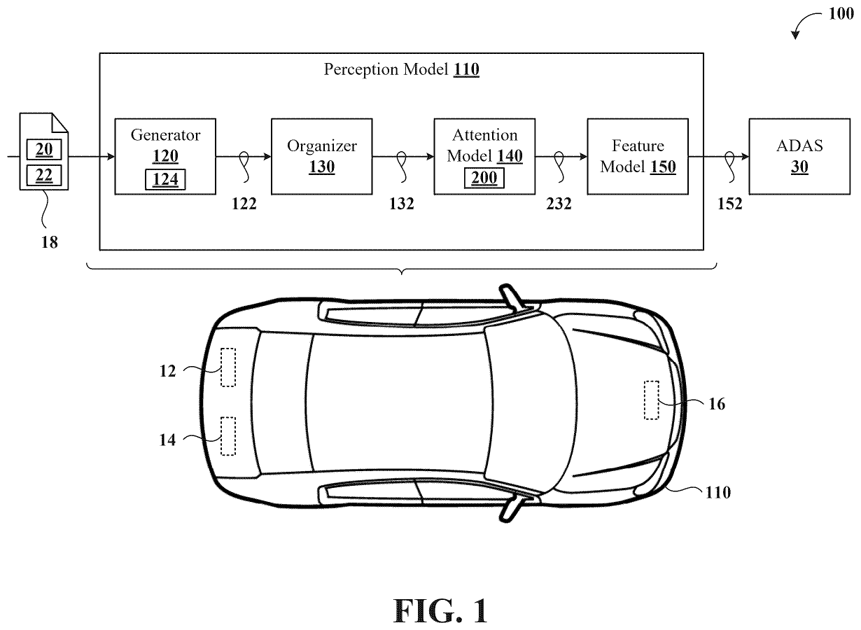

FIG. 1 illustrates a system 100 that includes a vehicle 10. The vehicle 10 contains data processing hardware 12 that is in communication with memory hardware 14. The data processing hardware 12 may be any suitable processor or group of processors capable of executing machine-readable instructions. For example, the data processing hardware 12 may include a central processing unit (CPU), a microcontroller, or a specialized processor such as a graphics processing unit (GPU), an application-specific integrated circuit (ASIC), or a field-programmable gate array (FPGA). The GPU, as one example, is well-suited for performing parallel computations common in deep learning models. The memory hardware 14 may be any non-transitory computer-readable medium, for example, random access memory (RAM), read-only memory (ROM), or other forms of volatile or non-volatile storage. The memory hardware 14 stores instructions that, when executed by the data processing hardware 12, cause the data processing hardware 12 to perform various operations described herein.

The vehicle 10 includes one or more sensors 16 configured to perceive the surrounding environment and produce sensor data. A sensor 16 could be, for example, a Light Detection and Ranging (LiDAR) sensor, a RADAR sensor, a stereo camera, or a time-of-flight camera. The sensor data produced by the one or more sensors 16 can take the form of a three-dimensional (3D) point cloud 18. A 3D point cloud 18 is a set of data points in a 3D coordinate system, representing the external surfaces of objects in the environment. The 3D point cloud 18 may include a large number of points 20, potentially hundreds of thousands or millions. Each respective point 20 of the one or more points 20 has corresponding coordinates 22. For example, a set of coordinates 22 could define the location of a point 20 in a Cartesian coordinate system (e.g., x, y, z values). Additionally, a point 20 may have other associated attributes, such as intensity, color, or a timestamp, which are also considered part of the sensor data.

The data processing hardware 12 executes a perception model 110 configured to process the 3D point cloud 18 and generate a high-level feature representation of the surrounding environment. This perception model 110 may be implemented as a neural network, such as a transformer-based architecture, designed to identify and learn complex spatial relationships and geometric structures within the point cloud data. For example, the perception model 110 may be trained to perform tasks such as object detection, semantic segmentation (e.g., classifying points as belonging to roadways, pedestrians, other vehicles, or vegetation), or motion prediction. The execution of the perception model 110 transforms the raw sensor data, specifically the 3D point cloud 18, into a structured and semantically rich feature representation that is suitable for downstream tasks, such as vehicle control and navigation planning. The perception model 110 is stored as a set of executable instructions and associated model parameters within the memory hardware 14.

The perception model 110 contains several interconnected components, including, for example, a generator 120, an organizer 130, an attention model 140, and a feature model 150, each configured to perform specific operations on the point cloud data. The generator 120 is configured to receive the 3D point cloud 18 as input and to partition the points 20 into a plurality of buckets 122. The generator 120 achieves this partitioning by applying a spatial hash function 124 to the coordinates 22 of each point 20 within the 3D point cloud 18. This spatial hash function 124 maps the continuous 3D spatial coordinates 22 of a point 20 to a discrete bucket index or identifier. As a result, points 20 that are located near one another in 3D space are mapped to the same bucket identifier. Consequently, each respective bucket 122 includes a corresponding group of spatially proximate points 20, effectively creating localized clusters of points based on geometric locality. For example, all points 20 representing a small patch of a roadway surface might be assigned to a single bucket 122 because their coordinates 22 are all within a defined spatial volume.

The spatial hash function 124 maps the 3D coordinates 22 of each point 20 to a discrete bucket index, and multiple types of hash functions can be used for this mapping. In some examples, the spatial hash function 124 includes at least one of an XOR-mod hash, an XOR-div hash, a Z-order-mod hash, or a Z-order-div hash. Each of these functions offers a different method for partitioning the 3D space, which in turn affects how points 20 are grouped together into buckets 122. For instance, a Z-order hash function operates by first quantizing the continuous coordinates 22 of a point 20 into discrete grid cell indices. For a point with coordinates (x, y, z), each coordinate is divided by a grid cell size and converted to an integer index (ix, iy, iz). The binary representations of these integer indices are then interleaved to produce a single Z-order code, also known as a Morton code. This interleaving process has the property that points 20 that are close in 3D space often have Z-order codes that are numerically close. The final bucket index is then determined from this Z-order code. For a Z-order-mod hash, the Z-order code is taken modulo the total number of buckets. For a Z-order-div hash, the Z-order code is divided by the number of points per bucket.

As another example, an XOR hash function also begins by quantizing the point coordinates 22 into integer grid indices (ix, iy, iz). The bucket index is then calculated by performing a bitwise XOR operation on these integer indices (e.g., hash=ix XOR iy XOR iz). This result can then be used directly or further processed. For an XOR-mod hash, the result of the XOR operation is taken modulo the total number of buckets. For an XOR-div hash, the XOR result is divided by a target bucket size. The choice of spatial hash function 124 influences the shape and distribution of the resulting buckets 122, thereby providing different ways to define geometric locality for subsequent processing stages.

After the generator 120 assigns a bucket index to each respective point 20, the organizer 130 physically reorders the points 20 within memory to form a contiguous block of memory 132. This arrangement operation is performed based on the bucket indices produced by the spatial hash function 124. Specifically, the organizer 130 sorts the points 20 according to the bucket index associated with each point 20. The result of this sorting operation is that all points 20 assigned to a same bucket 122 are grouped together and stored in adjacent memory locations within the contiguous block of memory 132. For example, if a first bucket has an index of 0 and contains ten points, and a second bucket has an index of 1 and contains fifteen points, the organizer 130 arranges the data such that the ten points for bucket 0 occupy the first block of memory, and the fifteen points for bucket 1 immediately follow in the next block of memory. This organization ensures that when a bucket 122 is accessed, the data for all points 20 within that bucket can be read from memory in a single, sequential operation, which is highly efficient for data processing hardware 12, such as a GPU. This contiguous memory layout is established once, prior to the plurality of attention iterations 200, and avoids the need for repeated, costly global shuffling operations between attention stages.

Thereafter, the attention model 140 performs a plurality of attention iterations 200 to progressively refine the point features. To facilitate the learning of both local and global spatial relationships, the grouping of points can be varied across different stages of the model. In some implementations, performing the plurality of attention iterations 200 includes partitioning the iterations into distinct groups, where each group utilizes a different methodology for establishing geometric locality. For example, the attention model 140 may perform a first group of iterations using a first spatial hash function 124 and subsequently perform a second group of iterations using a second spatial hash function 124, where the second spatial hash function 124 is different than the first spatial hash function 124.

This use of multiple spatial hash functions 124 provides a mechanism for re-grouping the points 20 without incurring the computational cost of physically reordering the data in the contiguous block of memory 132. For instance, the first spatial hash function 124 could be a Z-order-mod hash, which tends to create cubical or block-like buckets 122 that capture highly localized interactions. After a set number of attention iterations 200 using this grouping, the attention model 140 can switch to the second spatial hash function 124, such as an XOR-mod hash. An XOR-based hash often produces buckets 122 with more irregular, elongated shapes. By applying attention to these differently shaped buckets 122, the attention model 140 enables points 20 that were in separate buckets 122 under the first hashing scheme to be grouped together under the second hashing scheme. This effectively simulates the window shifting or shuffling used in other models but achieves the re-grouping logically through the selection of buckets 122 based on the different hash outputs, thereby enhancing the receptive field and ability of the model to learn longer-range dependencies between points 20. This multi-hash strategy offers greater flexibility in defining geometric locality at different stages of processing.

In some implementations, to create a hierarchical feature representation, the attention model 140, after performing at least one attention iteration 200, performs an in-bucket pooling operation on at least one bucket 122 of the plurality of buckets 122. This operation serves to downsample the points 20 within the at least one bucket 122, reducing the spatial resolution of the point cloud representation for subsequent processing stages. For example, a pooling operation may be applied after a group of attention iterations 200 is complete, preparing a reduced set of points for a next stage of feature extraction.

Performing the in-bucket pooling operation includes the attention model 140 partitioning the points 20 within the at least one bucket 122 into a plurality of sub-buckets. The partitioning of points 20 into sub-buckets may be based on a secondary spatial grouping within the local region defined by the bucket 122. After partitioning, the attention model 140 applies a reduction function to the point features within each sub-bucket. The reduction function aggregates the features of all points 20 within a sub-bucket to generate a single, reduced feature vector that represents that respective sub-bucket. Examples of a suitable reduction function include calculating an average of the point features (average pooling) or selecting a maximum value across the point features (max pooling). As a specific illustration, if a bucket 122 contains 64 points and is partitioned into 8 sub-buckets, applying the reduction function would result in 8 reduced feature vectors, one for each sub-bucket, effectively downsampling the representation of that bucket 122 by a factor of eight. A significant aspect of this operation is that the partitioning of the points 20 into the plurality of sub-buckets and the application of the reduction function are performed using the data already present within the cache 224. By executing this pooling operation on-chip, the system avoids costly data transfers to and from the contiguous block of memory 132, thereby improving computational speed and efficiency.

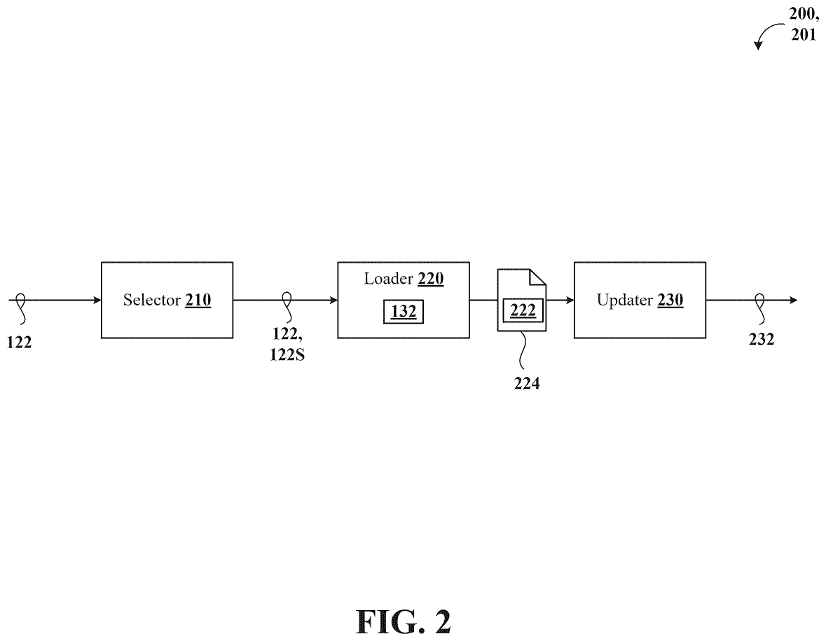

Referring now to FIG. 2, in some implementations, each attention iteration 201 includes a selector 210, a loader 220, and an updater 230. The selector 210 performs an operation to select a subset of the plurality of buckets 122 to define an attention scope for the current attention iteration 200. An attention scope defines the specific group of points 20 that will interact with one another during the multi-head self-attention operation. The selection of the subset of buckets 122 is a logical operation, meaning the selector 210 identifies which buckets 122 belong to the attention scope without physically reordering the points 20 within the contiguous block of memory 132. This logical selection maintains the data locality established by the organizer 130 and avoids the performance penalties associated with scattered memory access patterns.

In some examples, the selector 210 varies the subset of buckets 122 across subsequent attention iterations 200 to expand the receptive field of the attention model 140. For instance, selecting the subset of the plurality of buckets 122 in a subsequent attention iteration 200 may include selecting a shifted subset of buckets 122 relative to a preceding attention iteration 200. As an illustrative example, if a preceding attention scope included buckets with indices {0, 1, 2, 3}, a subsequent attention scope might be defined by a shifted set of indices, such as {2, 3, 4, 5}. This shifting strategy ensures that points 20 that were in separate attention scopes during one iteration can be grouped together in a later iteration, allowing the attention model 140 to learn longer-range dependencies between points 20. This logical shifting of the attention scope achieves a similar effect to window shifting in other transformer models, but without the computational overhead of physically rearranging the underlying data in the contiguous block of memory 132.

Subsequent to the logical selection of the attention scope by the selector 210, the loader 220 proceeds to load point features 222 from the contiguous block of memory 132 into a cache 224. The point features 222 correspond to the points 20 located within the buckets 122 that form the selected attention scope. In some examples, the data processing hardware 12 includes a graphics processing unit (GPU), and the cache 224 may include a high-speed local cache of the GPU, for example, an L1 cache or shared memory. This high-speed local cache offers significantly faster data access compared to the main GPU memory where the contiguous block of memory 132 resides. Because the organizer 130 has already arranged points 20 of the same bucket 122 into adjacent memory locations, the loader 220 can transfer the point features 222 for an entire bucket, or multiple buckets, as a single, coalesced memory transaction. This efficient transfer minimizes memory latency and maximizes bandwidth utilization.

To further optimize these loading operations, in some configurations, a size of each bucket 122 in the plurality of buckets 122 aligns with a memory tile size of the GPU. A memory tile is a unit of data that the GPU can load from main memory into the cache 224 in a single, efficient operation. For instance, if a GPU memory tile size is 128 kilobytes and each point feature 222 requires 2 kilobytes of storage, the generator 120 may define each bucket 122 to contain 64 points (64 points*2 KB/point=128 KB). By aligning the bucket size with the hardware-specific tile size, the loader 220 ensures that each memory access operation is maximally efficient, as a full tile of relevant data is loaded with a single instruction, preventing wasted bandwidth or fragmented reads.

Once the loader 220 populates the cache 224 with the point features 222, the updater 230 generates updated point features 232. The updater 230 accomplishes this by performing a multi-head self-attention operation on the loaded point features 222 currently residing within the cache 224. This operation calculates attention scores between pairs of points 20 within the attention scope, allowing the model to weigh the influence of different points when computing a new feature representation for each point. Performing the computationally intensive attention calculations entirely on-chip using the fast cache 224 avoids repeated access to the slower main memory, thereby accelerating the overall process.

After the attention model 140 completes the plurality of attention iterations 200, the resulting set of updated point features 232 encapsulates learned spatial relationships and geometric context from the 3D point cloud 18. The feature model 150 then processes these updated point features 232 to produce a final, high-level feature representation 152 of the 3D point cloud 18. This generation process may involve aggregating the updated point features 232 across all points 20 to form a single global feature vector that describes the entire scene. For example, the feature model 150 could apply a global pooling operation, such as max pooling or average pooling, to the collection of updated point features 232. In another example, the feature model 150 may apply one or more fully connected neural network layers to further transform the updated point features 232 into a more abstract and semantically rich format. The resulting feature representation 152 is a compact, structured summary of the input 3D point cloud 18, suitable for downstream perception tasks such as object detection, motion forecasting, or semantic segmentation.

The vehicle 10 may further include an advanced driver assistance system (ADAS) 30 that consumes the feature representation 152 to perform vehicle control operations. The ADAS 30 can be a system that provides functionalities ranging from driver alerts to fully autonomous control of the vehicle 10. The ADAS 30 processes the feature representation 152, which encodes a semantic understanding of the environment, to make informed decisions about vehicle behavior. For example, if the feature representation 152 indicates the presence and trajectory of a nearby vehicle, the ADAS 30 could initiate a longitudinal control action, such as adjusting the speed of the vehicle 10 to maintain a safe following distance. As another example, if the feature representation 152 identifies a pedestrian entering a crosswalk, the ADAS 30 might execute a braking maneuver. In another scenario, the ADAS 30 may use the feature representation 152 for lateral control, such as steering the vehicle 10 to stay within lane markings identified from the 3D point cloud 18. The control actions are then translated into commands for the actuators of the vehicle 10, for instance, the throttle, braking system, and steering system, thereby controlling the vehicle 10.

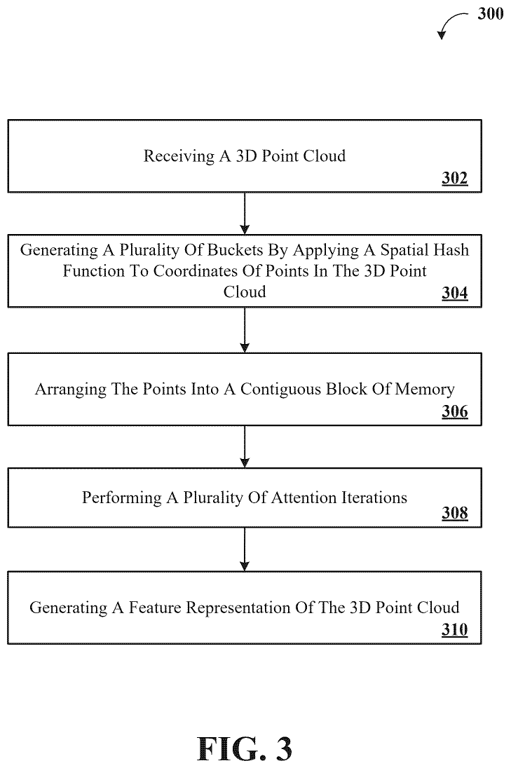

FIG. 3 is a flowchart of an example arrangement of operations for a computer-implemented method 300 of performing iterative attention scoping on spatially contiguous point cloud buckets. At operation 302, the method 300 includes receiving a three-dimensional (3D) point cloud. At operation 304, the method 300 includes generating a plurality of buckets 122 by applying a spatial hash function 124 to coordinates 22 of points 20 in the 3D point cloud 18. Each respective bucket 122 includes a corresponding group of spatially proximate points 20. At operation 306, the method 300 includes arranging, based on the spatial hash function 124, the points 20 into a contiguous block of memory 232. Points 20 assigned to a same bucket 122 are located in adjacent memory locations within the contiguous block of memory 232. At operation 308, the method 300 includes performing a plurality of attention iterations. Each attention iteration 200 includes selecting a subset of the plurality of buckets 122S to define an attention scope for the attention iteration 200, loading point features 222 corresponding to the points 20 in the attention scope from the contiguous block 232 of memory into a cache 224, and generating updated point features 232 by performing a multi-head self-attention operation on the loaded point features 222. The logical selection is performed without physically reordering the points 20 within the contiguous block of memory 232. At operation 310, the method 300 includes generating, based on the updated point features 232 from the plurality of attention iterations 200, a feature representation 152 of the 3D point cloud 18.

The disclosed systems and methods provide a computationally efficient framework for processing large-scale 3D point cloud data using transformer-based models. By arranging points into a contiguous block of memory based on a spatial hash function, the data is structured to align with the processing characteristics of parallel hardware, such as GPUs. This initial organization of points into spatially coherent buckets enables subsequent attention operations to be performed on localized groups of data loaded into a high-speed cache. This approach avoids the significant performance overhead associated with repeatedly reordering the entire point cloud in global memory between attention stages, a common bottleneck in other methods. Instead, different groupings of points are achieved through the logical selection of buckets for each attention scope, which allows for efficient, coalesced memory transfers and maximizes the utilization of available memory bandwidth.

A key aspect of this approach is the decoupling of geometric locality definition from the physical data layout. After an initial, one-time sort, the physical order of points in main memory remains static. The perception of local neighborhoods is altered logically, for example by applying different spatial hash functions in subsequent stages or by shifting the selection of buckets that form an attention scope. This logical re-grouping provides the flexibility to expand the model's receptive field and capture long-range dependencies between points without incurring the high cost of global data shuffling. Furthermore, the framework allows for efficient, on-chip downsampling through in-bucket pooling operations, further reducing data movement and accelerating hierarchical feature extraction. The combination of a cache-friendly data layout with logical attention scoping results in a substantial improvement in processing speed and scalability for analyzing 3D point cloud data.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A computer-implemented method executed on data processing hardware that causes the data processing hardware to perform operations comprising:
receiving a three-dimensional (3D) point cloud;
generating a plurality of buckets by applying a spatial hash function to coordinates of points in the 3D point cloud, wherein each respective bucket comprises a corresponding group of spatially proximate points;
arranging, based on the spatial hash function, the points into a contiguous block of memory, wherein points assigned to a same bucket are located in adjacent memory locations within the contiguous block of memory;
performing a plurality of attention iterations, each attention iteration comprising:
selecting a subset of the plurality of buckets to define an attention scope for the attention iteration, wherein the selection is performed without physically reordering the points within the contiguous block of memory;
loading point features corresponding to the points in the attention scope from the contiguous block of memory into a cache; and
generating updated point features by performing a multi-head self-attention operation on the loaded point features; and
generating, based on the updated point features from the plurality of attention iterations, a feature representation of the 3D point cloud.

2. The method of claim 1, wherein the spatial hash function comprises at least one of:
an XOR-mod hash;
an XOR-div hash;
a Z-order-mod hash; or
a Z-order-div hash.

3. The method of claim 2, wherein performing the plurality of attention iterations comprises:
performing a first group of iterations using a first spatial hash function; and
performing a second group of iterations using a second spatial hash function different than the first spatial hash function.

4. The method of claim 1, wherein selecting the subset of the plurality of buckets in a subsequent attention iteration comprises selecting a shifted subset of buckets relative to a preceding attention iteration.

5. The method of claim 1, wherein:
the data processing hardware comprises a graphics processing unit (GPU); and
the cache comprises a high-speed local cache of the GPU.

6. The method of claim 5, wherein a size of each bucket in the plurality of buckets aligns with a memory tile size of the GPU to optimize loading operations.

7. The method of claim 1, wherein the operations further comprise, after at least one attention iteration, performing an in-bucket pooling operation on at least one bucket of the plurality of buckets to downsample the points within the at least one bucket.

8. The method of claim 7, wherein performing the in-bucket pooling operation comprises:
partitioning the points within the at least one bucket into a plurality of sub-buckets; and
applying a reduction function to the point features within each sub-bucket to generate a reduced feature vector representing each respective sub-bucket.

9. The method of claim 8, wherein partitioning the points into the plurality of sub-buckets and applying the reduction function are performed entirely within the cache.

10. The method of claim 1, wherein the operations further comprise controlling a vehicle based on the feature representation of the 3D point cloud.

11. A vehicle comprising:
data processing hardware; and
memory hardware in communication with the data processing hardware, the memory hardware storing instructions that when executed on the data processing hardware cause the data processing hardware to perform operations comprising:
receiving a three-dimensional (3D) point cloud;
generating a plurality of buckets by applying a spatial hash function to coordinates of points in the 3D point cloud, wherein each respective bucket comprises a corresponding group of spatially proximate points;
arranging, based on the spatial hash function, the points into a contiguous block of memory, wherein points assigned to a same bucket are located in adjacent memory locations within the contiguous block of memory;
performing a plurality of attention iterations, each attention iteration comprising:
selecting a subset of the plurality of buckets to define an attention scope for the attention iteration, wherein the selection is performed without physically reordering the points within the contiguous block of memory;
loading point features corresponding to the points in the attention scope from the contiguous block of memory into a cache; and
generating updated point features by performing a multi-head self-attention operation on the loaded point features; and
generating, based on the updated point features from the plurality of attention iterations, a feature representation of the 3D point cloud.

12. The vehicle of claim 11, wherein the spatial hash function comprises at least one of:
an XOR-mod hash;
an XOR-div hash;
a Z-order-mod hash; or
a Z-order-div hash.

13. The vehicle of claim 12, wherein performing the plurality of attention iterations comprises:
performing a first group of iterations using a first spatial hash function; and
performing a second group of iterations using a second spatial hash function different than the first spatial hash function.

14. The vehicle of claim 11, wherein selecting the subset of the plurality of buckets in a subsequent attention iteration comprises selecting a shifted subset of buckets relative to a preceding attention iteration.

15. The vehicle of claim 11, wherein:
the data processing hardware comprises a graphics processing unit (GPU); and
the cache comprises a high-speed local cache of the GPU.

16. The vehicle of claim 15, wherein a size of each bucket in the plurality of buckets aligns with a memory tile size of the GPU to optimize loading operations.

17. The vehicle of claim 11, wherein the operations further comprise, after at least one attention iteration, performing an in-bucket pooling operation on at least one bucket of the plurality of buckets to downsample the points within the at least one bucket.

18. The vehicle of claim 17, wherein performing the in-bucket pooling operation comprises:
partitioning the points within the at least one bucket into a plurality of sub-buckets; and
applying a reduction function to the point features within each sub-bucket to generate a reduced feature vector representing each respective sub-bucket.

19. The vehicle of claim 18, wherein partitioning the points into the plurality of sub-buckets and applying the reduction function are performed entirely within the cache.

20. A computer-readable medium having instructions that, when executed by data processing hardware, causes the data processing hardware to perform operations comprising:
receiving a three-dimensional (3D) point cloud;
generating a plurality of buckets by applying a spatial hash function to coordinates of points in the 3D point cloud, wherein each respective bucket comprises a corresponding group of spatially proximate points;
arranging, based on the spatial hash function, the points into a contiguous block of memory, wherein points assigned to a same bucket are located in adjacent memory locations within the contiguous block of memory;
performing a plurality of attention iterations, each attention iteration comprising:
selecting a subset of the plurality of buckets to define an attention scope for the attention iteration, wherein the selection is performed without physically reordering the points within the contiguous block of memory;
loading point features corresponding to the points in the attention scope from the contiguous block of memory into a cache; and
generating updated point features by performing a multi-head self-attention operation on the loaded point features; and
generating, based on the updated point features from the plurality of attention iterations, a feature representation of the 3D point cloud.
